(19) United States
(12) Patent Application Publication
(10) Pub. No.: US 2011/0084612 A1
(43) Pub. Date: Apr. 14, 2011

(54) HYBRID CHIP-ON-HEATSINK DEVICE AND METHODS

(75) Inventors: William R. Ratcliffe, Thousand Oaks, CA (US); Jianbiao Pan, Avila Beach, CA (US)

(73) Assignee: GENERAL LED, INC., A DELAWARE CORPORATION, San Angelo, TX (US)

(21) Appl. No.: 12/707,641

(22) Filed: Feb. 17, 2010

Related U.S. Application Data
(60) Provisional application No. 61/250,426, filed on Oct. 9, 2009.

(51) Int. Cl. H01L 33/64; H01L 33/58; H01L 33/00; H01L 33/62; H05B 37/00

(52) U.S. Cl. 315/112; 257/99; 438/26; 257/98; 257/E33.075; 257/E33.066; 257/E33.059

(57) ABSTRACT

A hybrid chip-on-heatsink device comprises at least one LED die, at least one printed circuit board (PCB), and a thermally conductive substrate or heatsink. The LED die is physically and thermally coupled to the thermally conductive substrate. The PCB is physically coupled to the thermally conductive substrate. The LED die is electrically coupled to the PCB. The thermally conductive substrate acts as a spreader and as a heatsink, whereby heat is efficiently dissipated away from the LED die. The PCB may optionally contain other electrical components, and circuitry to create a “smart” LED package or light engine.

### CROSS-REFERENCE TO RELATED APPLICATION(S)

This document is a nonprovisional application that is related to, and claims priority from U.S. Provisional Patent Application Ser. No. 61/250,426, entitled “Hybrid Chip-on-Heat-Sink Packaged Device and Methods,” and filed on Oct. 9, 2009, which is commonly owned, and which is hereby incorporated by this reference in its entirety.

### BACKGROUND OF THE INVENTION

1. Technical Field

The present invention relates to devices and methods for low cost and high heat dissipation packaging of bare light emitting diodes (LEDs).

2. Related Art

Currently, high power (or high brightness) LED package designs incorporate several layers of heat spreaders or heat sinks and thermal interface materials (TIMs) between the bare LEDs and the ambient. These designs have high thermal resistance between the junction of LEDs and the ambient, which leads to high junction temperature of the LEDs. The complexity of these package designs also results in high cost manufacturing. High junction temperature of a LED die can significantly degrade the performance and reduce the life of the LED.

### SUMMARY OF THE INVENTION

Some embodiments of the invention advantageously provide a hybrid chip-on-heatsink device that provides low cost manufacturing and high heat dissipation by reducing thermal resistance, thereby resulting in high reliability and high performance in a device and method.

In one embodiment, the invention can be characterized as a hybrid chip-on-heatsink device, comprising at least one bare LED die, at least one printed circuit board (PCB), and a thermally conductive substrate (heatsink), the bare LED die being physically and thermally coupled to the thermally conductive substrate, the PCB being physically coupled to the thermally conductive substrate, the bare LED die being electrically coupled to a component of the PCB, and the thermally conductive substrate acting as a heat spreader and as a heatsink, whereby heat is efficiently dissipated away from the bare LED die.

In another embodiment, the invention can be characterized as a method of fabricating a hybrid chip-on-heatsink device, comprising steps of applying and curing a thermally conductive adhesive or soldering to physically and thermally couple the bare LED die to the thermally conductive substrate, applying and curing an adhesive to physically couple the PCB to the thermally conductive substrate, and wire bonding to electrically interconnect the bare LED die to a component of the PCB.

In a further embodiment, the invention can be characterized as a method of using a hybrid chip-on-heatsink device, comprising at least one bare LED die, at least one PCB, and a thermally conductive substrate (heatsink), the bare LED die being physically and thermally coupled to the thermally conductive substrate, the PCB being physically coupled to the thermally conductive substrate, the bare LED die being electrically coupled to a component of the PCB, and the thermally conductive substrate acting as a heat spreader and as a heatsink, whereby heat is efficiently dissipated away from the bare LED die, and applying a current to the device, thereby generating light from the LED die.

### BRIEF DESCRIPTION OF THE DRAWINGS

The above and other aspects, features and advantages of several embodiments of the present invention will be more apparent from the following more particular description thereof, presented in conjunction with the following drawings.

FIG. 1 is a side cross-sectional view of a hybrid chip-on-heatsink device with a bare LED die comprising an anode and a cathode on the same side of the LED die, in accordance with an embodiment of the present invention.

FIG. 2 is a side cross-sectional view of a hybrid chip-on-heatsink device with a bare LED die comprising an anode on the top and a cathode on the bottom side of the LED die, in accordance with an embodiment of the present invention.

FIG. 3 is a side cross-sectional view of a hybrid chip-on-heatsink device with a bare LED die comprising a cathode on the top and an anode on the bottom side of the LED die, in accordance with an embodiment of the present invention.

FIG. 4 is a side cross-sectional view of a hybrid chip-on-heatsink device incorporating the at least one bare LED die mounted in recesses of various configurations in the heatsink which serve to assist in positioning the LED die and to reflect and direct the light emitted from the LED die, and incorporating encapsulation and/or a lens, in accordance with a variation of the embodiments of FIGS. 1 through 3.

FIG. 5 is a top cut-away view of a hybrid chip-on-heatsink device employing a series of single heatsinks, each single heatsink supporting at least one bare LED die, in accordance with the variation of FIG. 4, and further being configured in a stringing arrangement, in accordance with an embodiment of the present invention.

FIG. 6 is a sectional view of a hybrid chip-on-heatsink device, comprising a single elongated hybrid chip-on-heatsink device, or alternatively, a plurality of elongated hybrid chip-on-heatsink devices, in accordance with a variation of the embodiment of FIG. 4 and further being configured in a row arrangement of FIG. 5, in accordance with an embodiment of the present invention.

FIG. 7 is a cross-sectional view of a hybrid chip-on-heatsink device, comprising an elongated hybrid chip-on-heatsink device, in accordance with a variation of the embodiment of FIG. 4, in accordance with an embodiment of the present invention.

FIG. 8 is a sectional view of a hybrid chip-on-heatsink device, comprising a plurality of hybrid chip-on-heatsink devices having a heatsink and generally configured in a shape of a down-light reflector, in accordance with another variation of the embodiment of FIG. 4.

FIG. 9 is a sectional view of a hybrid chip-on-heatsink device, comprising a plurality of hybrid chip-on-heatsink devices configured in a troffer-light arrangement, in accordance with another variation of the embodiment of FIG. 4.

FIG. 10 is a perspective view of a hybrid chip-on-heatsink device, in accordance with another variation of the embodiment of FIG. 4.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION OF THE INVENTION

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

Some embodiments of the present invention include, but are not limited to, providing a reduction of fabrication and assembly costs, providing a reduction of packaging sizes, i.e., miniaturization due to the integration of circuitry into a PCB, eliminating any intermediary packaging which would otherwise be required in related art devices, providing a high heat dissipation for improving performance, efficiency, and operational lifetime, providing a reduction of junction temperature of the LED die, and increasing device reliability.

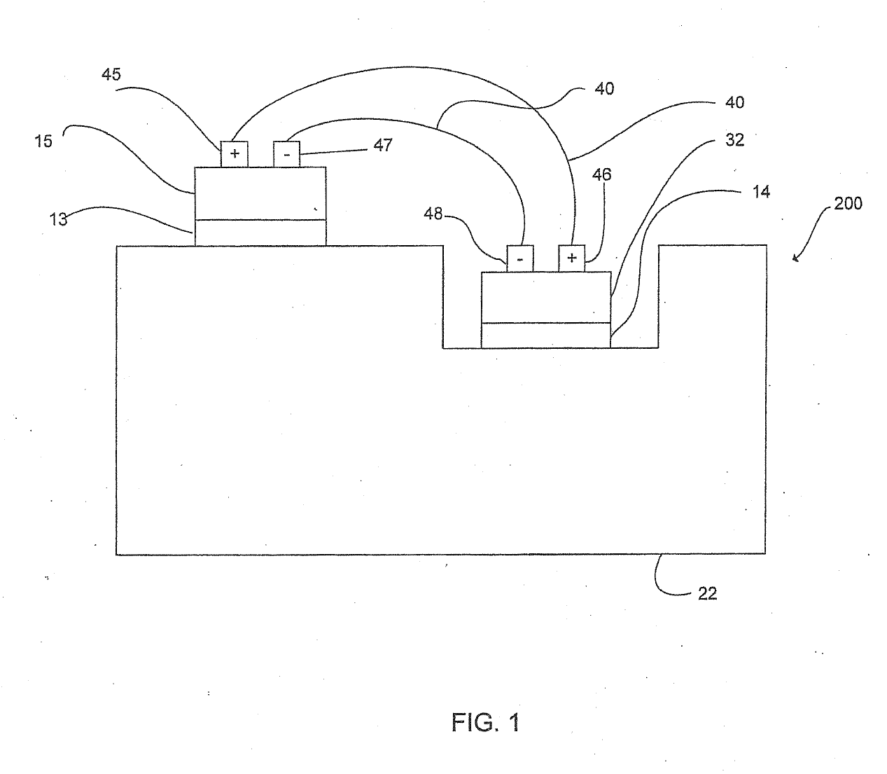

Referring first to FIG. 1, this side view cross-sectional diagram illustrates a hybrid chip-on-heatsink device 200 with at least one bare LED die 15 comprising an anode 45 and a cathode 47 on the same side of the LED die 15. The bare LED die 15 is physically and thermally coupled to the thermally conductive substrate 22 through applying and curing a thermally conductive adhesive or soldering 13 between them. The PCB 32 is physically coupled with an adhesive 14 to the thermally conductive substrate 22. The anode 45 and the cathode 47 of the bare LED die 15 are electrically interconnected to the component or components 46 & 48 of the PCB through wire bonds 40, in accordance with an embodiment of the present invention. An example of the component of the PCB is an electrically conductive pad, an electrical or electronic component mounted on, to or in the PCB, such as a resistor, a capacitor, a wire, trace, foil and/or other conductor, a coil, a choke, a transformer, and/or a semiconductor device, such as a diode, a transistor, an operational amplifier, an integrated circuit device, and/or the like.

Still referring to FIG. 1, the bare LED die or die array 15 is a light emitting material such as an inorganic LED die or an organic LED die. The wire bonds 40 may comprise at least one material, such as gold (Au), aluminum (Al), copper (Cu), and like materials. The PCB 32 may comprise at least one electrically conductive pattern formed by etching from an electrically conductive sheet such as copper, which is laminated onto an electrically insulating substrate such as a fiberglass, a polymer, an aramide, a polyimide, a polyamide, a liquid crystal polymer, a polycarbonate, a polyethylene, a polystyrene, and so on. The PCB 32 may also comprise an electrically insulating material printed or deposited onto an electrically conductive material and/or an electrically conductive material printed or deposited onto an electrically insulating material. The PCB 32 can be a rigid PCB 32, a flexible PCB 32, and/or a metal cored PCB 32. The thermally conductive substrate 22 comprises a material having a high thermal conductivity, e.g., a metal, such as aluminum, copper, an alloy, a thermally conductive ceramic material, a thermally conductive composite, and a conductive graphite material having a high thermal conductivity. The thermally conductive substrate 22 is formed by a technique, such as stamping, extruding, and machining, to minimize the overall manufacturing cost of the hybrid chip-on-heatsink device 200. The thermally conductive substrate 22 can be further tailored to meet a particular application and performance requirements. The thermally conductive substrate 22 may further comprise an enhanced heat dissipation feature, such as a fin structure to increase the thermally conductive surface area, an active cooling method, and so on.

The hybrid chip-on-heatsink device 200 may further comprise at least one electronic component (not shown) mounted onto and other circuitry disposed on, and electrically coupled with, the PCB 32 by a technique, such as wire bonding, flip chip bonding, tape automated bonding (TAB), a direct chip attach, a surface-mount technology (SMT), and/or a through-hole technology. The optional electronic component and other circuitry may comprise one or more of a resistor, a constant current driver, a capacitor, a microprocessor, an integrated circuit, a photocell, a piezotransducer, an inductor, a proximity switch, and/or any other suitable components. The integration of the optional electronic component and/or circuitry can result in smaller and more compact LED products.

Still referring to FIG. 1, in operation of the hybrid chip-on-heatsink device 200, the thermally conductive substrate 22 acts as a heat spreader and/or a heatsink, whereby heat is efficiently dissipated away from the LED die 15. Heat from the optional electronic components (not shown) of the PCB 32 is substantially isolated by the PCB 32, because the PCB 32 is substantially thermally insulating. As such, the LED die 15 does not experience adverse heat effects from the optional electronic components of the PCB, and the optional electronic components of the PCB do not experience adverse heat effects from the heatsink. The heat from the LED die 15 is transferred to the heatsink 22, transmitted away from the LED die 15, and dissipated into, e.g., the surrounding air or other heat transfer medium, e.g., a flowing liquid coolant in a conduit through or juxtaposed with the heatsink. The air, for example, may be moved across the heatsink 22 by convection or may be forced across the heatsink 22, such as by a fan. A junction-to-ambient thermal resistance is largely dominated by the thermal conductivity, the thickness, and the contact surface area of the thermal interface material between the LED die 15 and the heatsink 22. Directly attaching the LED die 15 to the heatsink 22 with the thin layer of thermally conductive adhesive, solder, or paste interposed therein between significantly reduces the thermal resistance between the junction of the LED die 15 and the heatsink 22. If a solder is used to physically connect the LED die 15 and the heatsink 22, a metallization layer is needed for both the LED die 15 and the heatsink 22 at the contact area.

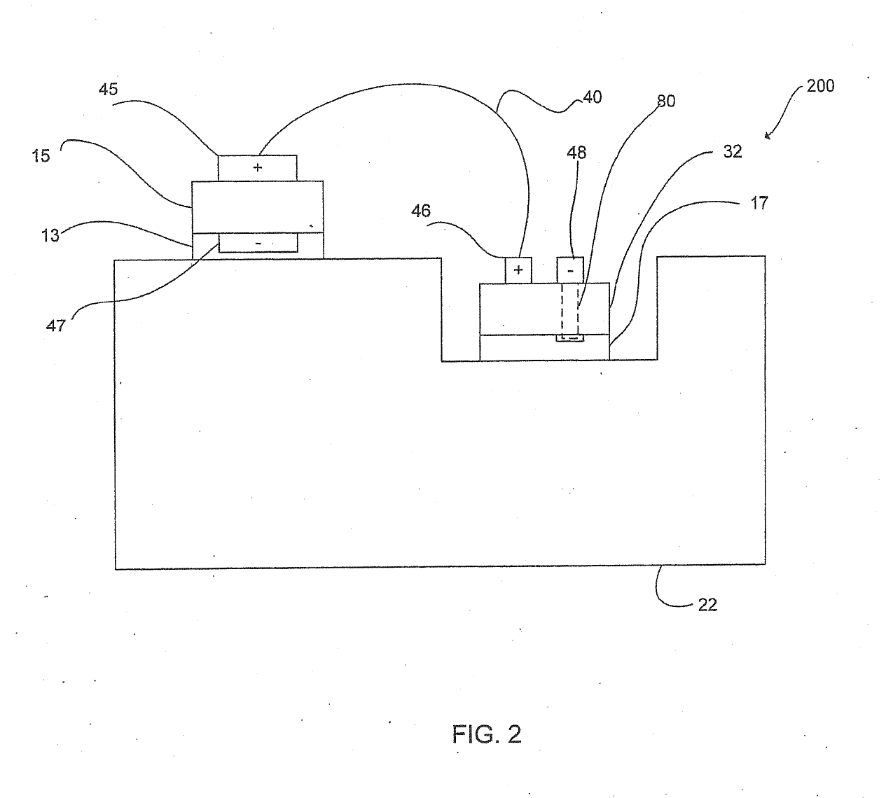

Referring next to FIG. 2, this side view cross-sectional diagram illustrates a hybrid chip-on-heatsink device 200 with a bare LED die 15 comprising an anode 45 on the top and a cathode 47 on the bottom side of the LED die. The bare LED die 15 is physically and thermally coupled to a heatsink 22 through applying a thermally conductive adhesive or a solder 13, with the anode 45 electrically coupled to a component 46 of PCB 32 through wire bonds 40, and the cathode 47 electrically coupled to another component 48 of the PCB 32 through the heatsink 22 by means of an electrically conductive via 80 formed in the PCB, wherein the PCB 32 is physically coupled with an electrically conductive adhesive or a solder 17 to the heatsink 22, in accordance with an embodiment of the present invention. The electrically conductive via 80 is formed by creating an orifice in the PCB 32 and subsequently plating the orifice and/or filling the orifice with an electrically conducting material.

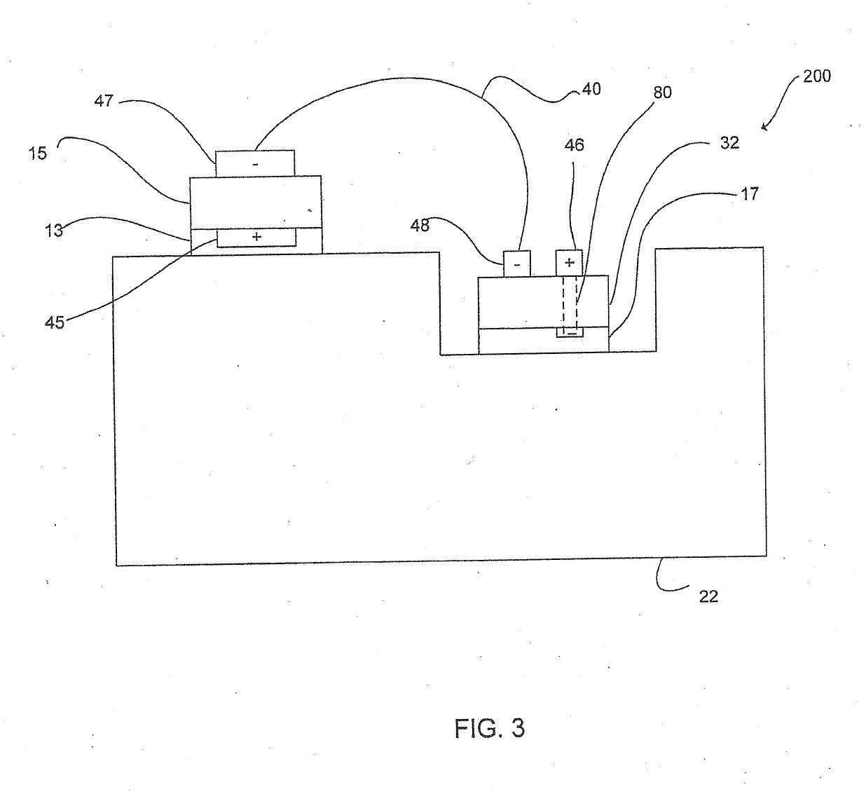

Referring next to FIG. 3, this side view cross-sectional diagram illustrates the same information as FIG. 2 with the exception of the anode and the cathode being reversed.

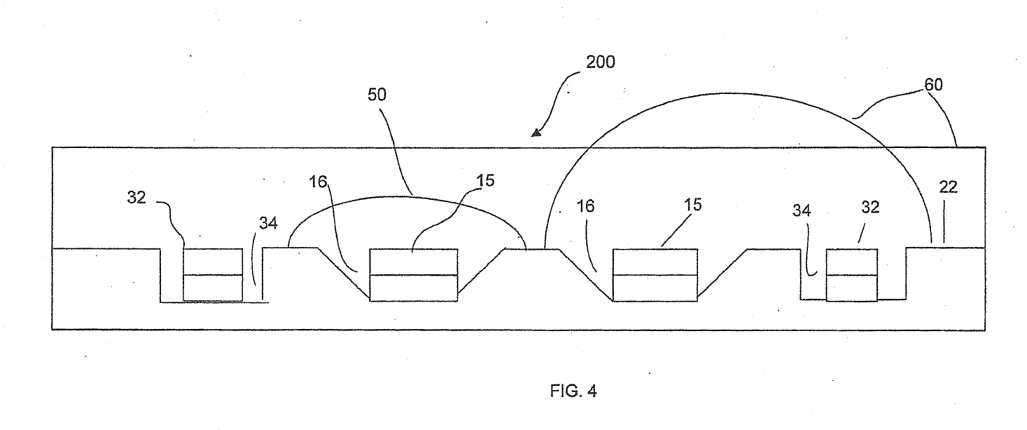

Referring next to FIG. 4, this side view cross-sectional diagram illustrates a hybrid chip-on-heatsink device 200, employing a thermally conductive substrate 22, to support multiple LED dies 15, such as in an array of LED dies 15, in accordance with a variation of the embodiments of FIGS. 1 through 3. Each LED die 15 in the array may comprise a distinct color or an array consisting of LED dies emitting in various colors. The heatsink 22 may comprise at least one cavity 16 for accommodating at least one LED die 15 and at least one cavity 34 for accommodating at least one PCB 32. The cavity 16 preferably comprises a shape that determines an angular spectrum or an angular dispersion of the light generated by the LED die 15. The shape is preferably selected from a group consisting essentially of parabolic shape, a frustoconical shape, and a trough shape (such as a trough having a rectangular shape, trapezoidal shape, or parabolic shape), for facilitating reflection and direction of the light generated by the LED die 15. The shape, such as a trough shape, may be formed by machining, extrusion, punching, casting, molding, or any combination of these processes of the heatsink 22. The cavity 16 may further comprise a light-directing feature, such as a reflective feature and a scattering feature. The reflective feature may comprise a feature, such as, for example, a polished surface, a plated surface, a painted surface, and a coated surface. The scattering feature may comprise, for example, a feature, such as a roughened surface topography.

Still referring to FIG. 4, an encapsulation may be used in a hybrid chip-on-heatsink device 200, in accordance with embodiments such as in FIGS. 1 through 3. The encapsulation 50 is disposed over and protects the LED die 15 and the wire bonds (not shown). The encapsulation 50 comprises an encapsulant material, e.g., an optically transparent or translucent encapsulant having a high refractive index or an optimally matched refractive index of the LED die 15, such as silicone, epoxy, and like materials. The encapsulation 50 provides an increased structural integrity, an increased environmental protection, and an enhanced photonic activity by having a high refractive index or a matched refractive index. The encapsulation 50 may also comprise a phosphor material (not shown) being integrated therein, in accordance with an embodiment of the present invention, such as for example coated onto an inside and/or outside of the encapsulation and/or impregnated therein, such as by being coated onto an inside and/or outside of the encapsulation, molded onto an inside and/or outside or the encapsulation, and/or mixed (such as in a particulate form) with a material forming the encapsulation, so as to be impregnated into the encapsulation. In another embodiment of the present invention, a plurality of quantum dots or nanoparticles may (not shown) be used instead of the phosphor material. The phosphor material and/or the plurality of quantum dots is excitable by impinging photons for enhancing a lighting effect, such as by providing for a color change from that emitted by the LED die itself and/or acting as a diffuser to the emitted light from the LED die.

Still referring to FIG. 4, a covering element 60, such as an optically clear lens or an opaque cover having at least one aperture for facilitating a passage of light, may be used in a hybrid chip-on-heatsink device 200, in accordance with an embodiment such as in FIGS. 1 through 3. The covering element 60 is physically coupled to the heatsink 22. The optically clear lens comprises an optically clear material, such as a plastic, a glass, and like materials. The covering element 60 is physically coupled to the heatsink 22 by a technique, such as integrally forming, adhering, and fastening. The optically clear lens may comprise a diffusion color matching the light output of an LED die, e.g., from a red, green, blue, or yellow LED. Various combinations and permutations of different color LED dies may be arranged to achieve a desired overall output color. The covering element 60 may be formed by a technique, such as molding or injection molding. The optically clear lens may also comprise a phosphor coating (not shown) or a phosphor (not shown) which is, for example, integrally molded into or coated onto the covering element 60 (or lens), in accordance with an embodiment of the present invention. In another embodiment of the present invention, a plurality of quantum dots or nanoparticles (not shown), which may be impregnated into the covering element 60, can be used instead of or in addition to the phosphor coating. The phosphor coating, or the plurality of quantum dots or nanoparticles, is excitable by impinging photons for enhancing a lighting effect. The distance between the LED die and the phosphor/quantum dots/nanoparticles can be optimized to obtain the desired light output performance and reliability. The opaque cover may further comprise at least one window element and may be formed by a technique, such as double injection molding and/or screen-printing. In the double-injection molding technique, the opaque cover is formed with at least one aperture in the first injection molding step; and a window filling the at least one aperture is formed in the second injection molding step, hence, the term double-injection molding. In the screen-printing technique, a clear cover is formed in the first step; and an opaque portion is screen-printed in a pattern, wherein at least one effective window is formed.

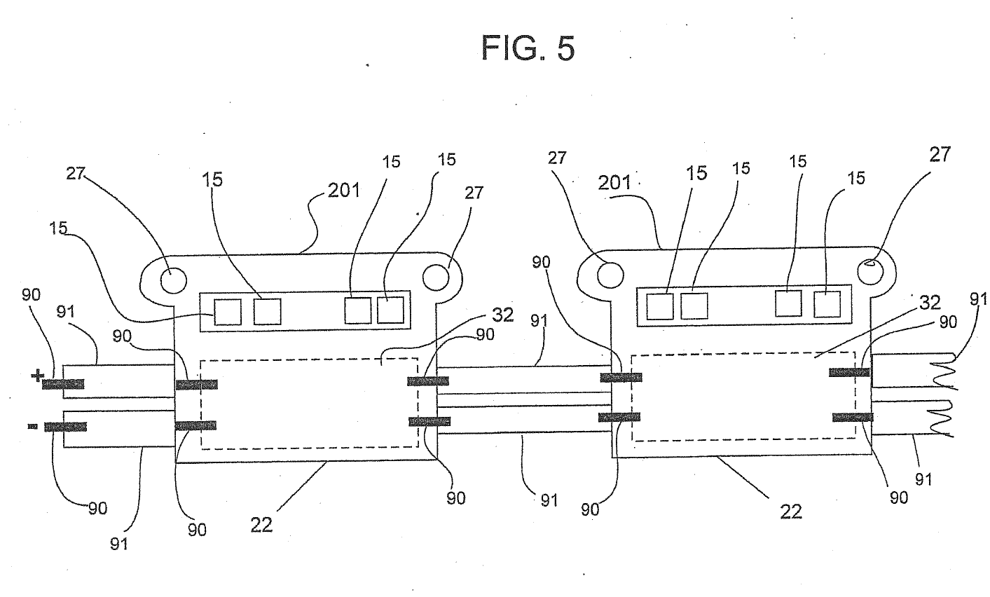

Referring next to FIG. 5, this top partial view illustrates a hybrid chip-on-heatsink device 201 employing a series of thermally conductive substrates 22 that support and are thermally coupled to multiple bare LED dies 15, in accordance with the variation of FIGS. 1-4, and further being configured in a stringing arrangement. The plurality of PCBs 32 that corresponds to the plurality of heatsinks 22 is electrically coupled by wires 90, having insulation 91, with adjacent ones of the plurality of PCBs 32. This embodiment can be flexibly configured to meet any illumination requirement based on the use of LED die 15, e.g., configuring a plurality of hybrid chip-on-heatsink devices 201 to suit various lighting needs. Each hybrid chip-on-heatsink device 201 may comprise at least one tap hole 27 for facilitating mounting the hybrid chip-on-heatsink device 201.

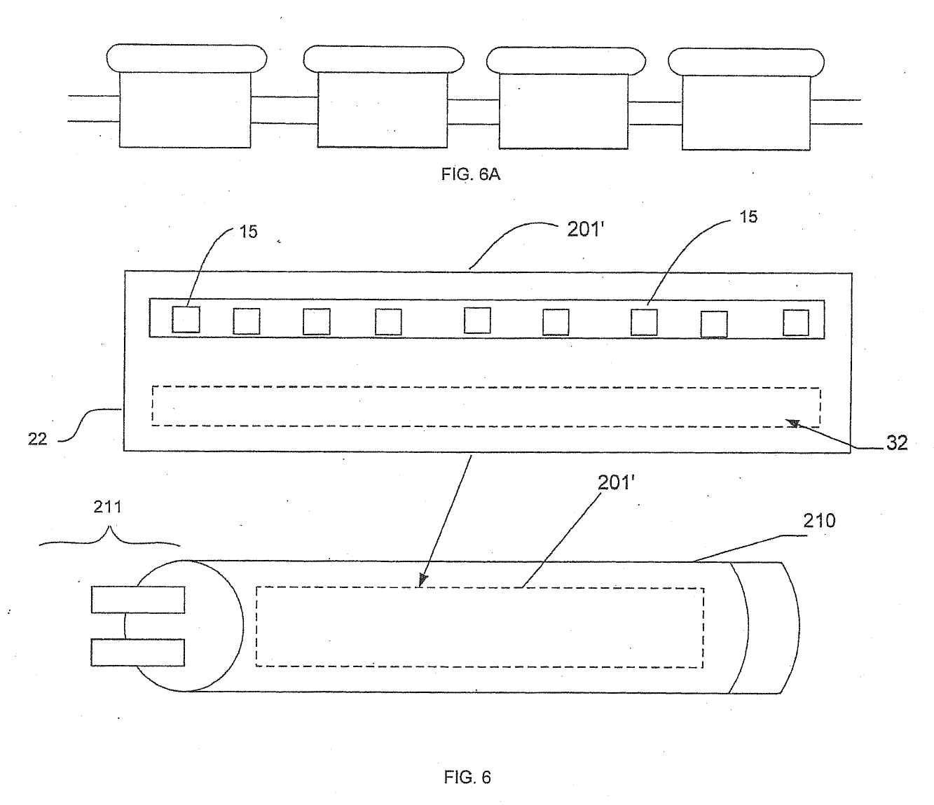

Referring next to FIG. 6, shown is an a sectional view of a hybrid chip-on-heatsink device 201′, comprising a single elongated hybrid chip-on-heatsink device, or alternatively, a plurality of elongated hybrid chip-on-heatsink devices, in accordance with a variation of the embodiment of FIG. 4, and further being configured in a row arrangement of FIG. 5 (as illustrated in FIG. 6A). This configuration may also be encased in a hollow elongated structure 210, e.g., a tube, such as a tube having an optical diffusion surface for diffusing light emitted from within the tube to create a diffuse light emission from the tube, thereby providing a packaged device in the form of a replacement, or alternative, product for a related art fluorescent tube or bulb (i.e., a fluorescent tube replacement device), the hollow elongated structure 210 having a structure 211 for electrically coupling the hybrid chip-on-heatsink device 201′ to a power source (not shown), such as electrical connections that are commonly used at ends of related art fluorescent tubes.

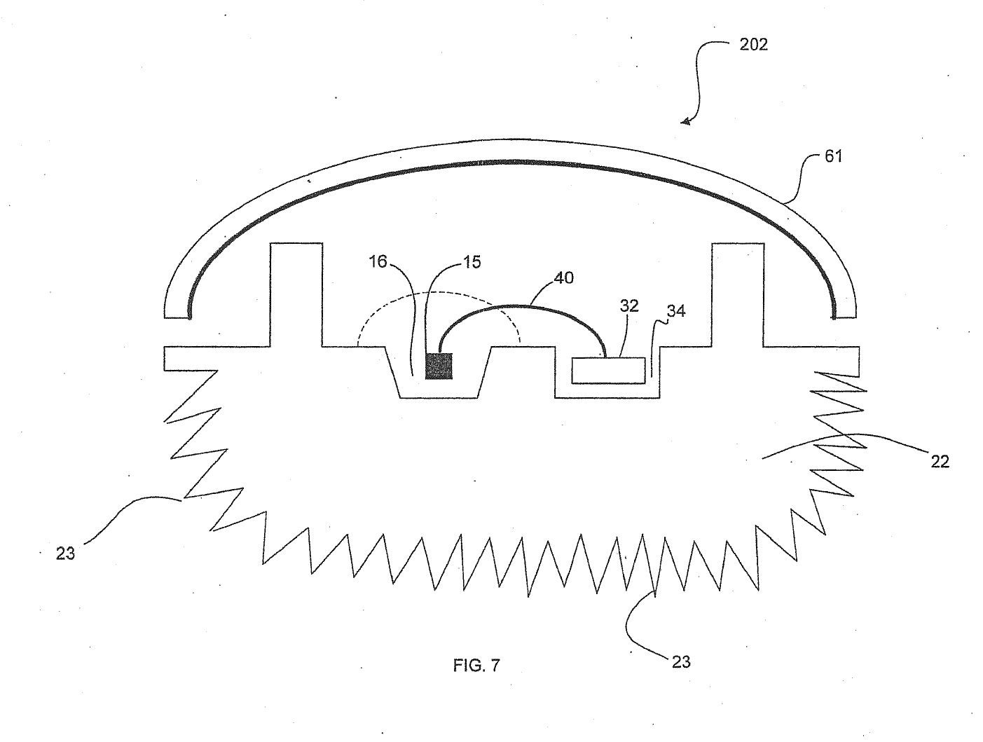

Referring next to FIG. 7, shown is a cross-sectional view of an elongated hybrid chip-on-heatsink device 202, in accordance with a variation of the embodiments of FIG. 4. Illustrated is a cross-sectional, axial view in which a major axis of the elongated hybrid chip-on-heatsink device 202 (such as the elongated chip-on-heatsink device of FIG. 6 201′) is normal to a plane through which the illustrated cross-section is taken. Shown is a heatsink 22, such as an extruded aluminum (or any other elongated heatsink suitable for a selected application, such as from the materials described hereinabove, and such as may be formed by extrusion, casting, machining or the like), having a plurality of external fins 23, and a light transmitting lens 61. Also shown is an LED die 15 (bare LED) or array of LED dies (LED array), a wire bond 40, and a PCB 32. The fins 23 are exposed outside of a cavity 16 formed between the lens 61 and the heatsink 22, which together with the heatsink 22 have a generally round or ellipsoidal shape in the cross section at an exterior, such as, for example, to generally comply with an exterior size and shape of a fluorescent tube, such as are known in the art. Within the cavity 16, the bare LED 15 or LED array is physically and thermally coupled to the heatsink 22, so that light emissions from the LED die 15 are directed to the lens 61, and are transmitted through the lens 61; the PCB 32 is physically coupled to the heatsink 22; and the LED is electrically coupled to the PCB 32, in accordance with the embodiments of FIGS. 1-3. In practice, the hybrid chip-on-heatsink device shown can be employed in a fluorescent tube direct replacement device, having been arranged with appropriate electrical terminals at ends thereof, so as to be physically and electrically compatible with a prescribed fluorescent fixture. As such, the hybrid chip-on-heatsink device 202 can be used as a replacement for a prescribed fluorescent tube in the prescribed fluorescent fixture. The PCB 32 is preferably an elongated strip of PCB materials (having a major axis normal to the plane through which the illustrated cross-section is taken) holding selected components thereon or therein.

Still referring to FIG. 7, the heatsink 22 is formed as an extrusion, having dimensions selected in accordance with a desired application, and being cut to a desired length. The LED dies 15 are picked and placed (such as by automated assembly equipment) at desired intervals along the heatsink, and physically and thermally coupled thereto, such as by a thermally conductive epoxy. The LED dies 15 may be placed in a cavity 16 with a shape selected for desired optical and/or thermal characteristics, such as a trough having a flat bottom against which the LED dies 15 are placed and sides that are angled to reflect light emitted from the LED dies generally at their sides toward the lens 61. Alternatively, the LED 15 dies may be placed on a generally flat planar surface of the heatsink 22. The elongated strip of PCB 32 is then placed into a cavity 34 in the heatsink 22, and physically coupled thereto, preferably remaining thermally isolated therefrom. The LED dies 15 are then wire bonded, preferably using automated equipment, to components, such as wire bond pads, on the PCB 32, which are electrically coupled to electrical and/or electronic devices (also/alternatively referred to herein as components of the PCB 32) on the PCB 32. Optionally, the LED dies 15 may be encapsulated with various encapsulation techniques, such as shown and described, for example, in reference to FIG. 4, as such as illustrated in FIG. 7 by the dashed line. Phosphors, and/or quantum dots or nanoparticles may be molded into, coated onto or impregnated into the lens 61, or encapsulation as described hereinabove.

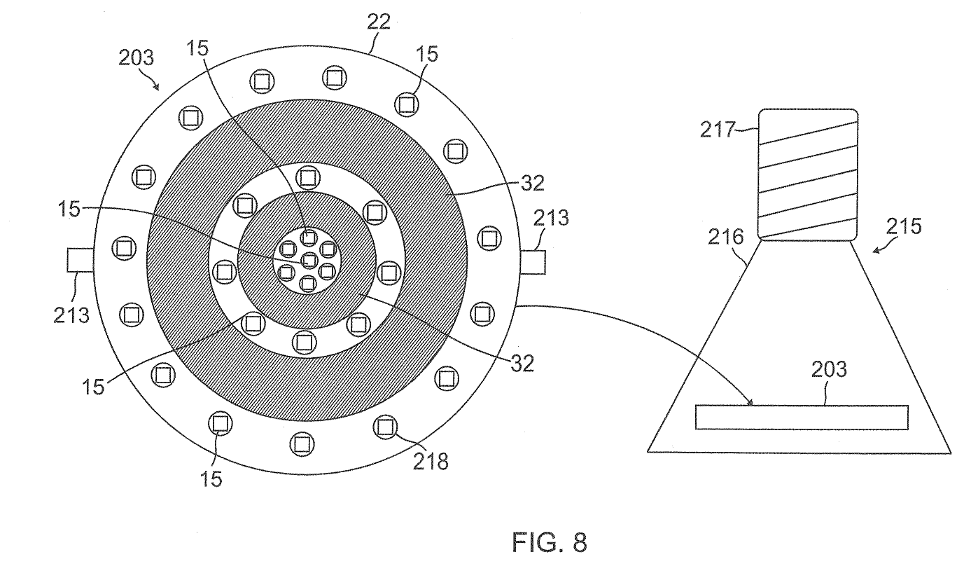

Referring next to FIG. 8, this sectional view illustrates a hybrid chip-on-heatsink device 203, comprising a hybrid chip-on-heatsink device having a plurality of LED dies 15 and a heatsink 22. The hybrid chip-on-heatsink device 203 is generally configured in a shape of a down-light reflector, thereby providing a packaged device in the form of a down-light, in accordance with another variation of the embodiments of FIG. 4. In this embodiment, the hybrid chip-on-heatsink device 203 comprises a plurality of LED dies 15 in a concentric ring formation, at least one PCB 32, and a heatsink 22. The device 203 may further comprise a plurality of lenses 218 (optional) that is transparent, translucent, or diffusing, the lenses 218 comprising a material, such as a polycarbonate diffuser. This embodiment, in some variations, may be configured in an LED luminary, e.g., thereby providing a packaged device in the form of a downwardly disposable LED luminary 215, by example only. The luminary 215 may comprise a bulb enclosure 216 (optional) and a structure 217 for coupling (optional) the luminary 215 to a power source (not shown). The designs of bulb enclosure 216 further enhances the overall heat sinking capability of the luminary through the use of a thermally conductive housing which also maximizes the surface thermally conducting area, e.g. fins, to which the LED heatsink is physically and thermally connected. The hybrid chip-on-heatsink device 203 may further comprise an electrical connector 213 (optional) with an optional mechanical locking member (optional and not shown). The bulb enclosure 216 supports and further protects the device 203; and the structure 217 couples the luminary 215 to the power source (not shown). This down-light arrangement functions well to meet applications, such as recessed lighting. The electrical connector 213 with a mechanical locking member (optional and not shown) is beneficial in providing better structural integrity for installation for the hybrid chip-on-heatsink device 203. This configuration is conductive for the replacement of the existing halogen, fluorescent, and incandescent luminaries such as industrial standard types MR-16, PAR30, PAR38, and so on, on a cost-effective, energy saving, and environmentally friendly basis.

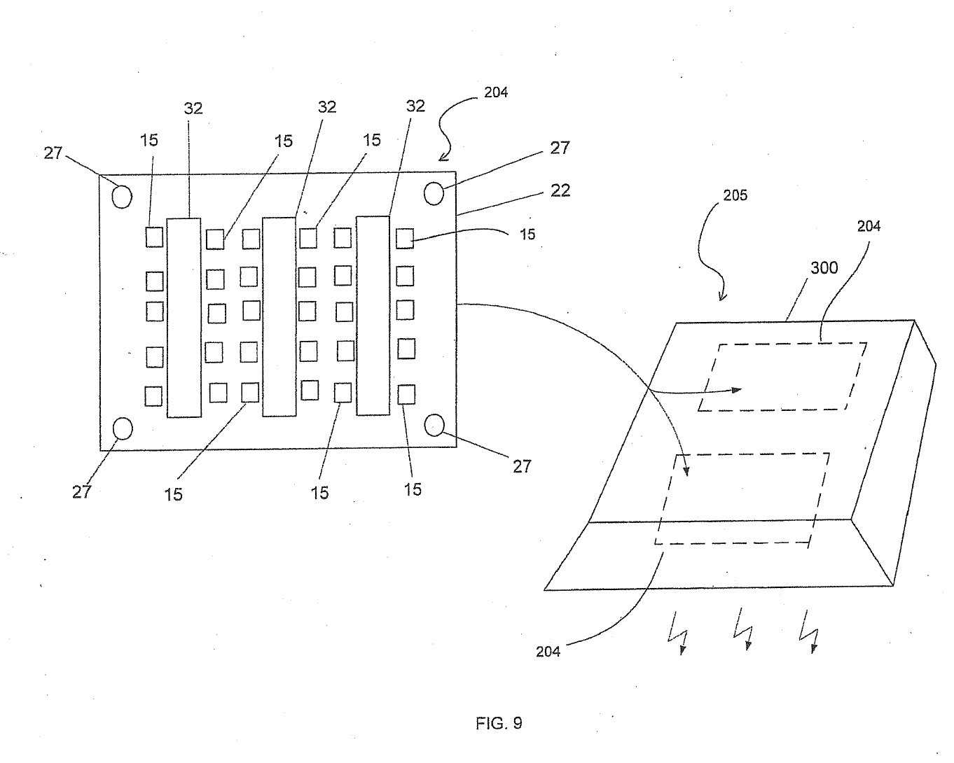

Referring next to FIG. 9, this sectional view illustrates a hybrid chip-on-heatsink device 204, comprising a plurality of hybrid chip-on-heatsink devices configured in a troffer-light arrangement, in accordance with the other variation of the embodiment of FIG. 4. The hybrid chip-on-heatsink device 204 comprises a plurality of LED dies 15 mounted in a plurality of rows, at least one PCB 32, and a heatsink 22. The hybrid chip-on-heatsink device 204 is generally configured in a planar configuration, thereby providing a packaged device in the form of a troffer assembly 205, by example only. The heatsink 22 may further comprise holes 27 for hybrid chip-on-heatsink device 204 in a housing 300, e.g., a troffer housing, to form the troffer assembly 205. The housing 300 may comprise a lens and a frame.

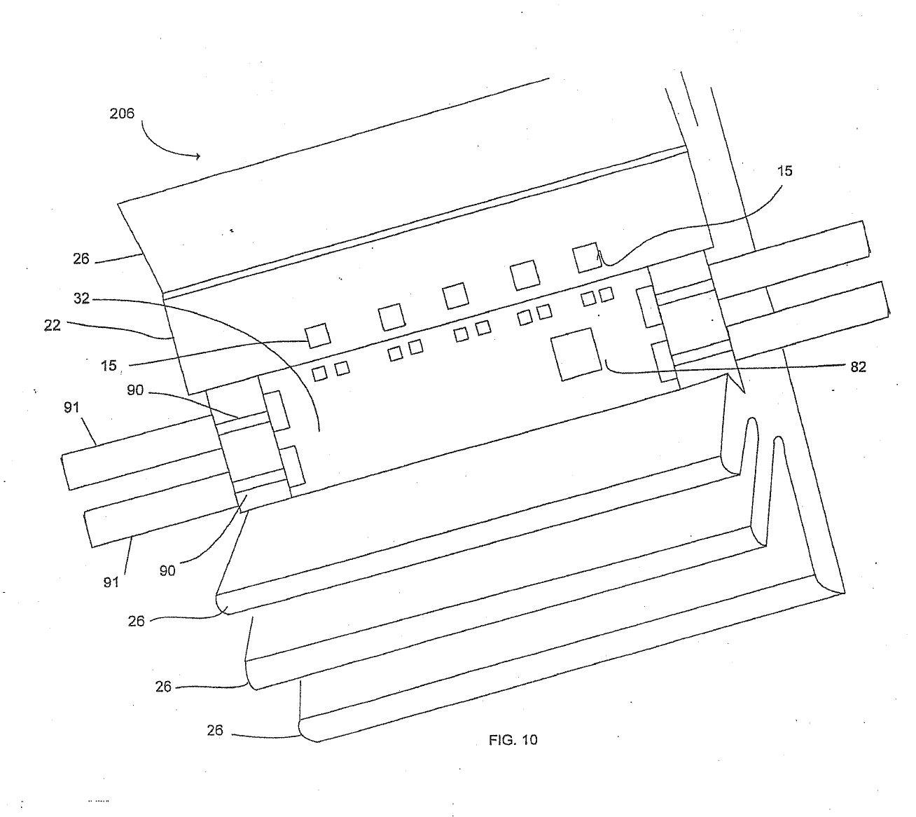

Referring next to FIG. 10, this perspective view illustrates a hybrid chip-on-heatsink device 206, comprising a hybrid chip-on-heatsink device having a plurality of at least one LED dies 15, at least one PCB 32, and a heatsink 22. The at least one PCB 32 may comprise at least one optional electronic component 82. The heatsink 22 may further comprise at least one heat dissipation feature, such as at least one fin 26 formed in a fanning formation for high power LED applications, such as street and parking lighting, and architectural flood lighting. The at least one LED die 15 is disposed lengthwise along the hybrid chip-on-heatsink device 206 in this embodiment. Wires 90 with insulation 91 provide power to the device 206. The at least one fin 26 formed in a fanning formation, provides substantial surface area for effectively transferring heat to the surrounding atmosphere. The angle of the fanning formation may facilitate reflection of light.

Information as herein shown and described in detail is fully capable of attaining one or more objects of embodiments of the invention, the presently preferred embodiment of the invention, and is, thus, representative of the subject matter which is broadly contemplated by embodiments of the present invention. The scope of the present invention fully encompasses other embodiments which may become obvious to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments that are known to those of ordinary skill in the art are hereby expressly incorporated by reference and are intended to be encompassed by the present claims.

Moreover, no requirement exists for a system or method to address each and every problem sought to be resolved by the present invention, for such to be encompassed by the present claims. Furthermore, no element, component, or method step in the present disclosure is intended to be dedicated to the public regardless of whether the element, component, or method step is explicitly recited in the claims. However, that various changes and modifications in form, material, and fabrication material detail may be made, without departing from the spirit and scope of the invention as set forth in the appended claims, should be readily apparent to those of ordinary skill in the art.

1. A hybrid chip-on-heatsink device, comprising:
at least one LED die;
at least one PCB; and
a thermally conductive substrate,
the at least one LED die being physically and thermally coupled to the thermally conductive substrate,
the at least one PCB being physically coupled to the thermally conductive substrate,
the at least one LED die being electrically coupled to a component of the at least one PCB, and
the thermally conductive substrate acting as a heat spreader and as a heatsink, whereby heat is efficiently dissipated away from the at least one LED die.

2. The device of claim 1, wherein the at least one LED die is a light emitting material such as an inorganic LED die or an organic LED die.

3. The device of claim 1, wherein the at least one PCB comprises at least one electrically conductive pattern and at least one electrically insulating layer.

4. The device of claim 1, wherein the thermally conductive substrate comprises at least one material, having a high thermal conductivity, selected from a group consisting essentially of a metal, aluminum, copper, an alloy, a thermally conductive ceramic, a thermally conductive composite, and a conductive graphite material.

5. The device of claim 1, further comprising at least one electrical/electronics component selected from a group consisting essentially of a resistor, a constant current driver, a capacitor, a microprocessor, an integrated circuit, a photocell, a piezo-transducer, an inductor, a proximity switch, and circuitry for facilitating smart-functioning of the device.

6. The device of claim 1, wherein the PCB further comprises an electrically conductive via which electrically couples the LED die and the PCB.

7. The device of claim 1, further comprising an encapsulation selected from a group consisting essentially of an optically transparent or translucent encapsulation.

8. The device of claim 1, further comprising a covering element selected from a group consisting essentially of an optically clear lens and an opaque cover having at least one aperture for facilitating illumination.

9. The device of claim 1, wherein the thermally conductive substrate comprise comprises at least one cavity for accommodating at least one element selected from a group consisting essentially of the at least one LED die and the at least one PCB.

10. A method of fabricating a hybrid chip-on-heatsink device, comprising:
providing at least one LED die; providing at least one PCB;
providing a thermally conductive substrate; physically coupling the at least one LED die to the thermally conductive substrate;
physically coupling the at least one PCB to the thermally conductive substrate; and
electrically coupling the at least one LED die to the at least one PCB,
whereby the thermally conductive substrate is capable of acting as a heat spreader and as a heatsink, and
whereby heat is capable of being efficiently dissipated away from the at least one LED die.

11. The fabrication method of claim 10, wherein the physically and thermally coupling of said at least one LED die includes applying and curing a thin layer of thermally conductive adhesive.

12. The fabrication method of claim 10, wherein the physically and thermally coupling of said at least one LED die includes soldering.

13. The fabrication method of claim 10, wherein the physically coupling of said at least one PCB onto the thermally conductive substrate includes applying and curing a thin layer of adhesive.

14. The fabrication method of claim 10, wherein forming said thermally conductive substrate is performed by at least one technique selected from a group consisting essentially of stamping, extruding, molding, casting, and machining.

15. The fabrication method of claim 10, wherein said electrically coupling of said at least one LED die to said at least one PCB includes wire bonding.

16. The fabrication method of claim 10, further comprising mounting at least one electronic/electrical component onto the at least one PCB.

17. The fabrication method of claim 16, wherein said mounting of said at least one component onto said PCB is performed by at least one technique selected from a group consisting essentially of a flip chip technique, a direct chip attach technique, a surface-mount technology (SMT), and a through-hole technology.

18. A method of using a hybrid chip-on-heatsink device, comprising at least one bare LED die, at least one PCB, and a thermally conductive substrate (heatsink) including:
physically and thermally coupling the at least one bare LED die to a thermally conductive substrate;
physically coupling the at least one PCB to the thermally conductive substrate;
electrically coupling the at least one bare LED die to the at least one PCB;
electrically energizing the at least one bare LED die, thereby generating light and heat;
spreading and sinking the heat in the thermally conductive substrate, whereby the heat is efficiently dissipated away from the at least one bare LED die.
